(19) United States
(12) Patent Application Publication
(10) Pub. No.: US 2006/0212767 A1
(43) Pub. Date: Sep. 21, 2006

(54) Production plant

(76) Inventor: Tiziano Agazzani, Modena (IT)

Correspondence Address: CNH AMERICA LLC, INTELLECTUAL PROPERTY LAW DEPARTMENT, PO BOX 1895, M.S. 641, NEW HOLLAND, PA, 17557, US

(21) Appl. No.: 11/354,710

(22) Filed: Feb. 15, 2006

(30) Foreign Application Priority Data
Feb. 15, 2005 (EP) EP 05425072 5

(51) Int. Cl. G01R 31/28

(52) U.S. Cl. 714/731

(57) ABSTRACT

A production plant having a number of machine tools, a number of tools/instruments, and a computer system having a number of first memory cells containing work cycle descriptions, a number of second memory cells containing operation descriptions, a number of third memory cells containing step descriptions, a number of fourth memory cells containing first ties between each first memory cell and a number of second memory cells, and a number of fifth memory cells containing second ties between each second memory cell and a number of third memory cells.

### FIELD OF THE INVENTION

The invention relates to a method of relating changes in data records to the operation of tools (especially machine tools); and to a production plant. The invention may be used to advantage in a machine shop (or workshop), to which the following description refers purely by way of example.

### BACKGROUND OF THE INVENTION

A workshop comprises a number of machine tools, each for performing a given range of machining operations, and a number of tools/instruments and other implements such as gauges and other metrology devices, and may carry out a large number of machining processes, each for producing a given mechanical part.

To ensure all the machining processes are carried out properly (in terms of both the end result and operator safety), international quality standards (in particular ISO 9000) require that each machining process be adequately documented. In the case of paper documentation ISO 9000 requires that each document be drawn up in five stamped, numbered, certified copies.

When producing a part using one or more machine tools, the first document to be drawn up is the work cycle, which lists all the operations by which a workpiece becomes a finished part. Each operation in the work cycle has a progressive identification number; a description of the machine tool to be used (possibly the machine tool location within the workshop); and a description of the work to be carried out on the workpiece, and which is normally defined by an orderly succession of elementary jobs/operations known as phases.

Current international standards require that, for each phase in an operation, a respective card be drawn up documenting the tool to use, the machining plan, and any other necessary information. Thus the card provides the operator with detailed information on how to carry out the required work on any given mechanical part.

In a medium- or large-sized workshop, the amount of documentation involved in accurately describing each step in each possible work cycle is therefore extensive and is often burdensome. Moreover, whenever changes are made to a tool or to the way in which the work is performed, all the relative cards must also be altered. Creating and, above all, continually updating all the documentation involved is therefore an extremely time-consuming, high-cost process.

Computer systems to automate creation and management of such documentation have been proposed, and which provide for creating and updating electronic documents that are printable on demand. Such documents, however, are none other than electronic versions of the corresponding paper documents, and are managed in exactly the same way. Consequently, although updating is more efficient than using conventional paper documents, the time factor involved is still considerable.

### SUMMARY OF THE INVENTION

According to a first aspect of the invention there is provided a method of relating changes, in a plurality of data records describing and/or defining a plurality of activities that are capable of being performed by a plurality of tools, to the operations of the tools themselves, the method comprising the steps of, in one or more memory devices,
a. providing a plurality of first memory locations each containing data defining a work cycle;
b. providing a plurality of second memory locations each containing data defining an operation that may form part of a said work cycle, each said operation comprising one or more phases;
c. providing a plurality of third memory locations each containing data defining a said phase;
d. providing a plurality of fourth memory locations each containing data relating to a part to be manufactured;
e. providing a plurality of fifth memory locations each containing data relating to an implement to be used in one or more of the phases; and
f. linking the data in the memory locations such that the data are combinable to create a plurality of data sets each including (i) the identification and/or characteristics of a part selected from the data in the fourth memory location, (ii) the identification and/or characteristics of one or more implements selected from the data in the fifth memory location and (iii) data defining a series of steps employing the or each implement and selected from the data in the first, second and third memory locations that amount to the manufacture of the part using the selected implement or implements, characterized in that the linking of the data is such as to cause automatic updating of linked data on the updating of any individual item of data.

The ability simultaneously to update several linked documents (or other data files) is unique in the environment of a tool-based production machine. This facility moreover permits the saving of considerable amounts of time when effecting updates. Indeed the time saving involved is so significant that it is out of proportion with the workrate that could be achieved using manual updating techniques as are available in the prior art.

Preferably in accordance with the method of the invention each data set is producible as a single document comprising a mix of graphical, numeric and textual data. This feature advantageously permits the method of the invention to include the method step of displaying the document (including the aforesaid mix of data types) via a display device such as a computer monitor. To this end the method of the invention may include the step of activating a software program known as a viewer for the purpose of displaying the document.

The method of the invention conveniently includes the step of creating and/or maintaining an address database containing data in one or more of the following classes:
a. configuration information including one or more paths by means of which a program may access data from the memory locations and activate one or more viewers permitting viewing of the data sets;
b. machine type information;
c. machine identification information;
d. supplier information;
e. machine and plant manufacturer information;
f. information identifying parts to be produced;
g. plant information;
h. information on departments of a plant involved in the manufacture of parts; and
i. tool composition information.

The method also operationally includes the steps of creating and/or maintaining a document database containing data in one or more of the following classes:
a. document codes;
b. user identification data;
c. document format information;
d. document type information;
e. document location information;
f. engineer identification information;
g. costing information;
h. information on data creation dates; and
i. information on the booking of documents and the statuses booked to them, and of creating and/or maintaining a part database containing data in one or more of the following classes:
   i. information identifying a product in which a part is installable;
   ii. part type information;
   iii. part code information;
   iv. part description information;
   v. database revision information; and
   vi. part production status information.

These various databases advantageously contain the information, that may require linking when practicing the method of the invention, in logically grouped sets.

The method of the invention also optionally includes the steps of creating one or more work cycle data sets, operation data sets, phase data sets, implement data sets, cutting information data sets and cycle-operation-phase-part sequence data sets.

The method of the invention optionally may include the step of performing a data entry operation in order to create or update one or more data sets.

It is therefore an advantage of the invention to provide a production machine, which is cheap and easy to implement, and which, at the same time, is designed to eliminate the drawbacks of prior art production machines.

A non-limiting embodiment of the present invention will be described by way of example with reference to the accompanying drawings.

### BRIEF DESCRIPTION OF THE DRAWINGS

FIG. 1 shows a schematic view of a production machine in accordance with the present invention.

FIG. 2 shows a diagram of the memory structure of a computer system of the FIG. 1 machine.

FIG. 3 shows a prior art CAD document.

FIG. 4 shows a document produced and updated in accordance with the invention.

### DETAILED DESCRIPTION OF THE PREFERRED EMBODIMENTS

In accordance with the method of the invention it is possible to create a series of databases each containing logically grouped sets of data. The respective data sets relate to respective hierarchical strata of a work cycle by following which it is possible to carry out production operations such as machining of a part. The databases are linked such that updating of data in one of them automatically effects corresponding updates in the other, linked databases.

Such an arrangement permits updating of linked data sets (which may if desired by displayed, using a viewer, and printed in the manner of document files) in considerably less time than would be possible, even if a production machine were able to allocate a large number of personnel to the updating task.

The first database to be considered is a generalized resource database typically but not necessarily including, inter alia, address data, machine type data, machine identification data, supplier data, machine and manufacturer data, data on parts produced by the manufacturing machine, drawings, schematics such as wiring diagrams, machine identification data, factory departmental data and tool composition data. This database is used for reference purposes and in particular in order to identify and locate drawings and specifications automatically. It may or may not in any given embodiment of the invention be linked so as to permit automated updating of its contents on the completion of an updating operation in another database.

The address data set (which typically is a lookup table) contains path information employed when practicing the method of the invention in order to allow a software program (such as a database management program) to access executable programs such as viewers.

A document database typically may contain for each item of data a data entry identification code, and a document identification code, a user identification code (for example identifying a department that might make use of the document in question), a document format code (signifying whether the document is in paper format, text format, computer-aided design (CAD) format and so on); a document type code (signifying whether the document concerns a fixture, a drilling or other shaping tool, a part to be manufactured, an electrical schematic and so on); a description of the document; a code indicating where the document is stored; a code identifying the engineer responsible for generating the document; document cost data in units such as hours, data on the dates of creation, logging and updating of the document, and data signifying the status of the document for example in terms of whether it is “booked”, “assigned” or “deleted”, these terms in turn indicating whether it is at a given time permissible to make use of the data in the document in question.

Not all of the foregoing fields in the document database will necessarily be completed in respect of every document in the database. Possibly some fields will be empty in respect of all documents in the database (for example if a particular condition, that would affect all documents, had not arisen).

A part database includes:
a. information identifying a product in which a part is installable;
b. part type information;
c. part code information;
d. part description information;
e. database revision information; and
f. part production status information.

One example (of many possible examples) of a product in which a part is installable is a vehicle such as a tractor.

Following creating of such databases the method of the invention involves, in respect of each part to be manufactured, the creation of a work cycle data set containing one or more of a cycle code, cycle type information and a description of a cycle.

The cycle code is an identifier such as a number. The cycle type information might signify (for example by means of a text string) a designation of a cycle such as “main” (ie. in use), “old” (not in use) and so on. The cycle description may also be a text string.

The method also involves the provision of an operation data set specifying, in respect of each operation, an operation identifier, a said cycle code, an operation number, an operation description, machine type information, individual machine identification, the “type position” in a said machine at which an operation takes place, machine position information, an operation description and a machine description.

Of the foregoing data arguably only the “type position” data are not self-explanatory. The “type position” data relates to for example machining lines in which a partly-finished part is moved from machining centre to machining centre (or from position to position) along the line. The “type position” data specifies the type of machining apparatus employed, according to a code.

Similarly the machine position information may signify for example the precise position, in a machining line, at which an operation takes place.

The description of the operation typically contains only minimal detail.

A phase data set is created, in accordance with the method of the invention, comprising one or more of phase identification data, a phase description and information identifying one or more parts on which a phase may be carried out. These data are believed to be self-explanatory to one of skill in the manufacturing art.

The method also involves creating an implement data set containing one or more of a data element identifier, one or more said phase identification data, implement quantity information, implement type information, an implement code, one or more said operation identifiers, implement usage frequency data, implement usage unit of measure data, and date of creation and amendment data, the implement data set linking implement data, part programs and the phase data together; a cutting information data set containing one or more of a data element identifier, phase identification information, tool diameter data, tool quantity data, tool cutting speed data, tool cutting edge number data and feed per edge data, the cutting information data set linking cutting information to the phase; and a cycle-operation-phase-part sequence data set, containing one or more of a data element identifier, a cycle identifier, an operation identifier, a phase number code, a phase identifier and a part identifier, the said data elements being linked in the data set.

In the implement data set the “implement” may be for example a boring tool, a milling cutter, a metrology gauge or any of a range of similar devices that may be employed in the manufacture of a part.

The main advantage of providing data in the indicated formats relates to the linking of the data as signified. This permits in effect the simultaneous updating of a vast number of potential documents. This is because each document is made up of individual data sets from the linked databases. Thus it is necessary to update only the database in question that is involved in any change. It is not necessary to update each document in which the changed data might appear, since the documents are created in real time (employing appropriate viewer software) from the linked data elements.

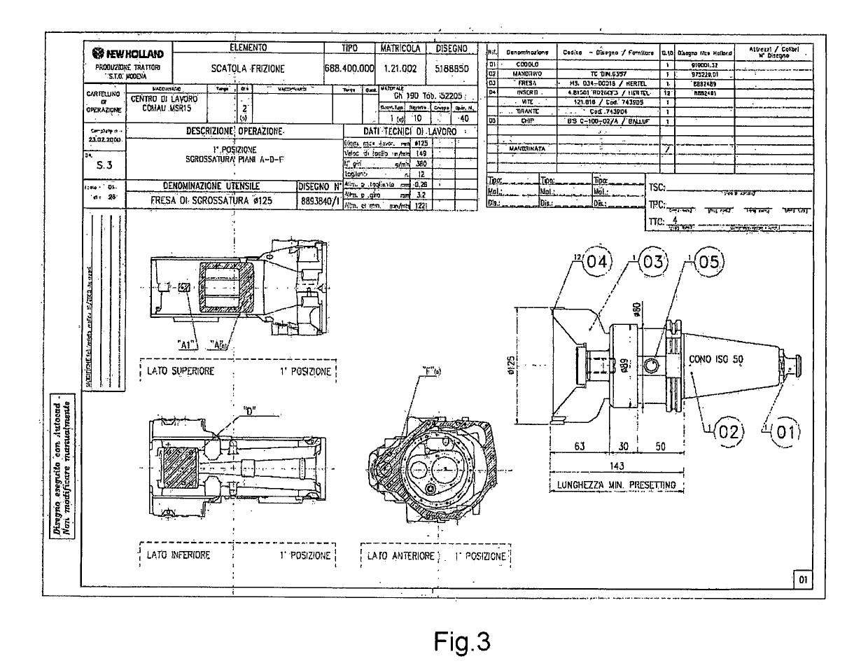

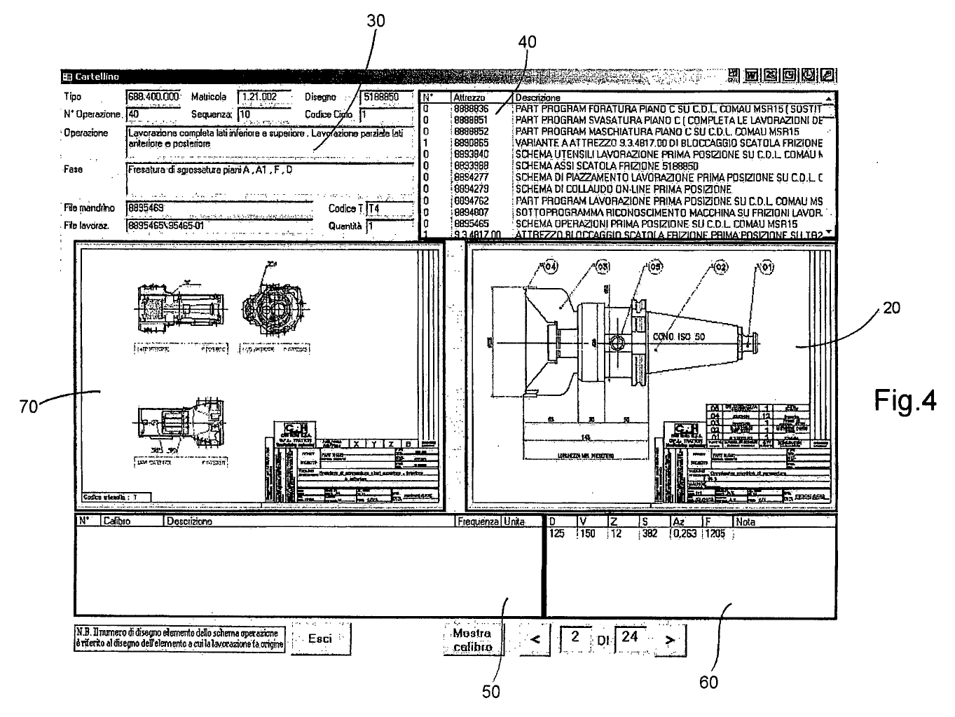

This principle is best exemplified, in a simple manner, by FIGS. 3 and 4 appended hereto. FIG. 3 shows a prior art CAD drawing used in one operation (comprising one or more phases) in the production of (in the example shown) a vehicle transmission housing. FIG. 3 shows three views of the part in question (i.e. the transmission housing) together with (on the right hand side of the drawing) an elevational view of the tool needed for the operation in question. The FIG. 3 drawing contains inter alia information identifying the operation in question together with tool feed, speed and diameter data.

In the case of the FIG. 3 drawing however, the various images plus the data tables shown may exist in other documents (for example if the tool in question has to complete a different operation on the same part, or even an operation on a different part). Thus any change to one part of the FIG. 3 document may require the effecting of corresponding updates in numerous other documents in order to ensure consistency. This is so even if the document of FIG. 3 is stored electronically, and represents a very significant document updating burden.

In contrast, the FIG. 4 document is produced in accordance with the method of the invention. In the FIG. 4 document the various images (10,20) of the exemplary transmission housing and the tool, plus the data tables (30,40,50,60) shown, are produced as windows and contain data from the linked databases described above. Thus the FIG. 4 document is created in real time by combining together the contents of various parts of the database. It follows that updating of one part of the document (say, altering the design of an aspect of the transmission housing) needs only to be effected in the relevant window shown (in this case window 10, although changes to the other windows are possible) for the update to take effect in all the documents employing the thus updated data set.

Of course if such a change to the transmission housing necessitates changes to, for example, the tabular data as well a simple update operation would cause the table update to take effect in all the documents requiring both the tabular data and the transmission housing images to be shown together. Such updating, which derives from the use of linked databases as aforesaid, gives rise to an entirely new manner of relating document changes, across a number of documents in a production environment. Such an updating method could not be achieved through human effort alone. For this reason, in practice the method is carried out using a suitably programmed computer.

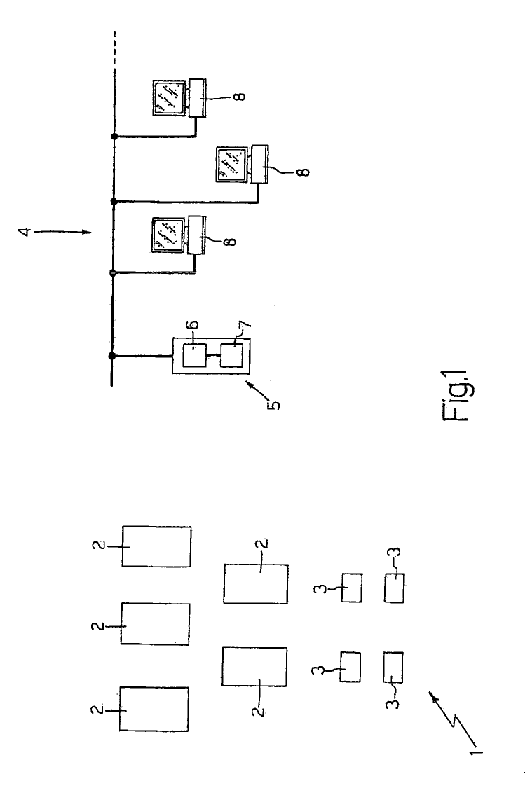

In view of the foregoing the invention is considered also to reside in the production of documents according to the method defined and/or described herein. To this end in a practical factory arrangement, as shown in FIG. 1 according to the invention, numeral 1 indicates a workshop comprising a number of machine tools 2, each for performing a given range of machining operations, and a number of tools/instruments 3.

To ensure all the machining processes are carried out properly (in terms of both the end result and operator safety), each machining process must be adequately documented. For which purpose, workshop 1 also comprises a computer system 4 for storing work cycle description documentation.

When producing a part using one or more machine tools 2, the first document to be drawn up is the work cycle, which lists all the operations by which a workpiece becomes a finished part; and each operation is defined by an orderly succession of elementary jobs/operations known as steps.

Computer system 4 comprises at least one server computer 5 having a processing unit 6 and a memory 7 (typically a hard disk); and a number of customer computers 8 network connected to server computer 5.

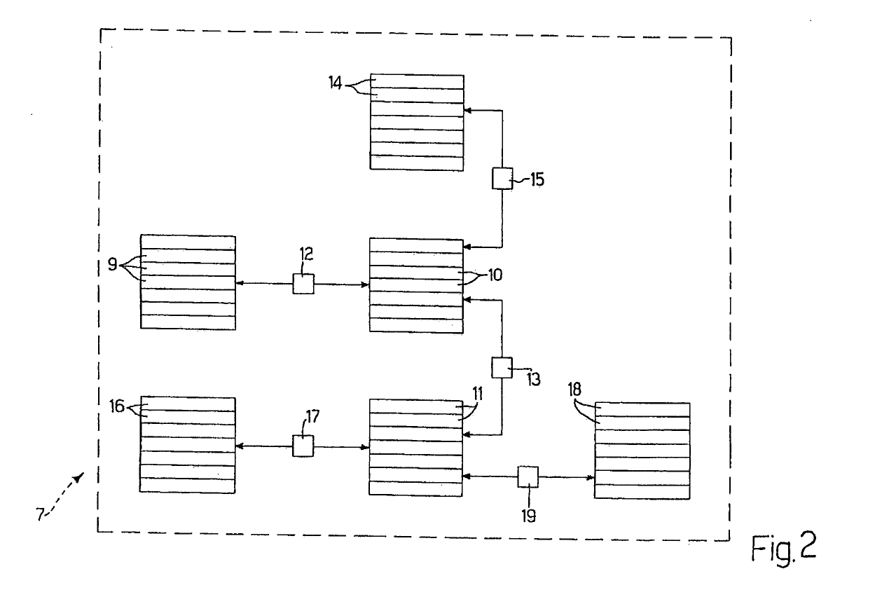

As shown in FIG. 2, memory 7 of server computer 5 comprises a number of memory cells 9 organized into a work cycle table, and each containing a description of a given work cycle. To describe a work cycle, each memory cell 9 in the work cycle table comprises an identification code and a text description.

Memory 7 of server computer 5 also comprises a number of memory cells 10 organized into an operations table, and each containing a description of a given operation. To describe an operation, each memory cell 10 in the operations table comprises a progressive identification code number, a text description of the work to be carried out on the part, a description of the machine tool 2 to be used, and, if necessary, the location of machine tool 2 within workshop 1.

Memory 7 of server computer 5 also comprises a number of memory cells 11 organized into a step table, and each containing a description of a given step. To describe a step, each memory cell 11 in the step table comprises a progressive identification code number, a text description of the work to be carried out, and a text field for any comments.

Memory 7 of server computer 5 comprises a number of memory cells 12 containing ties, which associate a number of memory cells 10 in the operations table with each memory cell 9 in the work cycle table, so that each work cycle is assigned a list of operations by which a workpiece becomes a finished part.

Memory 7 of server computer 5 comprises a number of memory cells 13 containing ties, which associate a number of memory cells 11 in the step table with each memory cell 10 in the operations table, so that each operation is assigned a list of steps to be performed to complete the operation.

In a preferred embodiment, memory 7 of server computer 5 comprises a number of memory cells 14 organized into a part table, and each containing a part identification number, a text description of the part, and a part drawing reference (typically the storage address). Memory 7 of server computer 5 also comprises a number of memory cells 15 containing ties, which associate a number of memory cells 14 in the part table with each memory cell 10 in the operations table, so that each operation is assigned a list of parts that can be machined using that particular operation. It should be stressed that memory cells 9 in the work cycle table and memory cells 10 in the operations table contain no information concerning the part for machining, the work cycle and the part for machining being related solely by the ties in memory cells 15. The reason for this is that the same work cycle may be used for machining different parts. For example, if the work cycle of a new part comprises the same operations as an existing work cycle, the new part need simply be assigned the existing work cycle to obtain complete documentation of the work carried out on the new part.

In a preferred embodiment, each memory cell 1 in the step table is also assigned further step-performance information. More specifically, each memory cell 11 in the step table is assigned operating parameters of the tool/instrument 3 to be used (eg. test frequency, cutting speed, feed rate, etc.); reference to at least one drawing of a tool/instrument 3 to be used; and reference to at least one work drawing. Drawings are preferably stored in a drawing data bank, in which each drawing has its own address for easy display. Each memory cell 11 in the step table is therefore also assigned a complete list of the tools/instruments 3 required to perform the step.

For which purpose, memory 7 of server computer 5 comprises a number of memory cells 16 organized into an operation parameter table, and each containing the operating parameters of the tool/instrument 3 to be used. Memory 7 of server computer 5 also comprises a number of memory cells 17 containing ties, which associate a number of memory cells 16 in the operating parameter table with each memory cell 11 in the step table, so that each step is assigned a series of operating parameters.

Memory 7 of server computer 5 comprises a number of memory cells 18 organized into a tool table, and each containing a progressive identification code number, a tool/instrument 3 drawing reference (typically the storage address), and a work drawing reference (typically the storage address). Memory 7 of server computer 5 also comprises a number of memory cells 19 containing ties, which associate a number of memory cells 18 in the tool table with each memory cell 11 in the step table, so that each step is assigned at least one tool.

It should be stressed that the tool/instrument 3 drawing and the work drawing are not combined into one drawing, but are obviously related by a respective step, so that any alteration to a tool/instrument 3 drawing or to a work drawing is automatically reflected in all the steps in which the drawing is referenced. Moreover, if a tool/instrument 3 is used for different operations on a number of parts, one tool/instrument 3 drawing is sufficient and need simply be assigned to a number of steps.

In one possible embodiment, each memory cell 11 in the step table and/or each memory cell 10 in the operations table also comprises an indication of estimated work time and/or estimated work cost.

Processing unit 6 of server computer 5 preferably provides for “copy & paste” operations to speed up creation of new documents from existing ones. That is, a memory cell 9, 10, 11 or 14 can be duplicated together with all the relative ties in memory cells 12, 13 or 15 to subsequently modify the duplicate.

Memory cells 12, 13, 15, 17 and 18 containing the ties may be organized into one or more tie tables, or may be associated with the corresponding memory cells 9, 10, 11, 14, 16 or 18.

Computer system 4 as described above has numerous advantages, by enabling documentation to be created and updated rapidly and efficiently, and to be distributed in real time.

Computer system 4 provides for extensive real-time information, such as which operations a given tool/instrument 3 is used for, or a complete list of the tools/instruments 3 required to work a given part. Knowing what is required to produce a given part, and what a given tool/instrument 3 is used to produce, any proposed alterations to tools/instruments 3 can be assessed beforehand in terms of involvement of other machining operations.

Finally, by means of connection to the drawing data bank, computer system 4 generates and distributes documentation within the plant with no risk of involuntary tampering, by distributing copies as opposed to original drawings.

I claim:

1. A method of relating changes, in a plurality of data records describing a plurality of activities that are capable of being performed by a plurality of tools, to the operations of the tools themselves, the method comprising the steps of, in one or more memory devices, providing a plurality of first memory locations each containing data defining a work cycle;
providing a plurality of second memory locations each containing data defining an operation that may form part of a said work cycle, each said operation comprising one or more phases;
providing a plurality of third memory locations each containing data defining a said phase;
providing a plurality of fourth memory locations each containing data relating to a part to be manufactured;
providing a plurality of fifth memory locations each containing data relating to an implement to be used in one or more of the phases; and
linking the data in the memory locations such that the data are combinable to create a plurality of data sets each including:
information of a part selected from the data in the fourth memory location;
information of one or more implements selected from the data in the fifth memory location; and
data defining a series of steps employing at least one implement and selected from the data in the first, second and third memory locations that amount to the manufacture of the part using the selected implement or implements, characterized in that the linking of the data is such as to cause automatic updating of linked data on the updating of any individual item of data.

2. A method according to claim 1 wherein each data set is producible as a single document comprising a mix of graphical, numeric and textual data.

3. A method according to claim 2 including the step of displaying the document via a display device.

4. A method according to claim 1 including the step of creating or maintaining an address database containing data in at least one of the following classes:
configuration information including one or more paths by means of which a program may access data from the memory locations and activate one or more viewers permitting viewing of the data sets;
machine type information;
machine identification information;
supplier information;
machine and machine manufacturer information;
information identifying parts to be produced;
plant information information on departments of a plant involved in the manufacture of parts; and
tool composition information.

5. A method according to claim 1 including the step of creating or maintaining a document database containing data in one or more of the following classes:
document codes;
user identification data;
document format information;
document type information;
document location information;
engineer identification information;
costing information;
information on data creation dates; and
information on the booking of documents and the statuses booked to them.

6. A method according to claim 1 including the step of creating or maintaining a part database containing data in one or more of the following classes:
information identifying a product in which a part is installable;
part type information;
part code information;
part description information;
database revision information; and
part production status information.

7. A method according to claim 1 including the step of creating a work cycle data set containing one or more of a cycle code, cycle type information and a description of a cycle.

8. A method according to claim 7 including the step of creating an operation data set containing one or more of an operation identifier, a said cycle code, an operation number, an operation description, machine type information, individual machine identification, the “type position” in a said machine at which an operation takes place, machine position information, an operation description, and a machine description.

9. A method according to claim 8 including the step of creating a phase data set containing one or more of phase identification data, a phase description and information identifying one or more parts on which a phase may be carried out.

10. A method according to claim 9 including the step of creating an implement data set containing one or more of a data element identifier, one or more said phase identification data, implement quantity information, implement type information, an implement code, one or more said operation identifiers, implement usage frequency data, implement usage unit of measure data, and date of creation and amendment data, the implement data set linking implement data, part programs and the phase data together.

11. A method according to claim 10 including the step of creating a cutting information data set containing one or more of a data element identifier, phase identification information, tool diameter data, tool quantity data, tool cutting speed data, tool cutting edge number data and feed per edge data, the cutting information data set linking cutting information to the phase.

12. A method according to claim 11 including the step of creating a cycle-operation-phase-part sequence data set, containing one or more of a data element identifier, a cycle identifier, an operation identifier, a phase number code, a phase identifier and a part identifier, the said data elements being linked in the data set.

13. A method according to claim 12 including the step of performing a data entry operation in order to create or update one or more data sets.

14. A method according to claim 1 including the step of activating a viewer to permit the display of documents generated in accordance with the method.

15. A production plant comprising a number of machine tools, each for performing a given range of machining operations; a number of tools/instruments; and a computer system for memorizing descriptive documentation of possible work cycles; the said production plant being characterized in that the computer system comprises:
a number of first memory cells organized into a work cycle table, and each containing a description of a given work cycle;
a number of second member cells organized into an operations table, and each containing a description of a given operation;
a number of third memory cells organized into a step table, and each containing a description of a given step;
a number of fourth memory cells containing first ties, which associate a number of second memory cells in the operations table with each first memory cell in the work cycle table, so that each work cycle is assigned a list of operations by which a workpiece becomes a finished part; and
a number of fifth memory cells containing second ties, which associate a number of third memory cells in the step table with each second memory cell in the operations table, so that each operation is assigned a list of steps by which to complete the operation.

16. A production plant as claimed in claim 15, wherein, to describe a work cycle, each first memory cell in the work cycle table comprises an identification code and a text description.

17. A production plant as claimed in claim 15, wherein, to describe an operation, each second memory cell in the operations table comprises a progressive identification code number, a text description of the work to be carried out on the part, and a description of the machine tool to be used to perform the work.

18. A production plant as claimed in claim 17, wherein, to describe an operation, each second memory cell in the operations table comprises a location, within the production plant, of the machine tool to be used.

19. A production plant as claimed in claim 17, wherein each second memory cell in the operations table comprises an indication of estimated work time or estimated work cost.

20. A production plant as claimed in claim 15, wherein, to describe a step, each third memory cell in the step table comprises a progressive identification code number, and a text description of the work to be carried out.

21. A production plant as claimed in claim 16 wherein, to describe a step, each third memory cell in the step table is associated with operating parameters of the tool or instrument to be used.

22. A production plant as claimed in claim 17, further comprising:
a number of sixth memory cells organized into an operating parameter table, and each containing operating parameters of the tool or instrument to be used; and
a number of seventh memory cells containing ties, which associate a number of sixth memory cells in the operating parameter table with each third memory cell in the step table, so that each step is assigned a series of operating parameters.

23. A production plant as claimed in claim 20, wherein, to describe a step, each third memory cell is associated with at least one drawing of a tool to use, and at least one work drawing.

24. A production plant as claimed in claim 23, further comprising:
a number of eighth memory cells organized into a tool table, and each containing a progressive identification code number, a reference to a drawing of a tool or instrument, and a reference to a work drawing; and
a number of ninth memory cells containing ties, which associate a number of eighth memory cells in the tool table with each third memory cell in the step table, so that each step is assigned at least one tool.

25. A production plant as claimed in claim 20, wherein each third memory cell in the step table comprises an indication of estimated work time or cost.

26. A production plant as claimed in claim 15, further comprising:
a number of tenth memory cells organized into a part table, each containing a description of a part; and
a number of eleventh memory cells containing third ties, which associate a number of tenth memory cells in the part table with each second memory cell in the operations table, so that each operation is assigned a list of parts that can be worked by the operation.

27. A production plant as claimed in claim 15, further comprising a processing unit for duplicating a memory cell together with all relative ties.
